(19) United States
(12) Patent Application Publication
(10) Pub. No.: US 2006/0273782 A1
(43) Pub. Date: Dec. 7, 2006

(54) Method of, and apparatus for, measuring the quality of a printed image

(76) Inventors: David John Galton, Essex (GB); Roy R. Rosenberger, Appleton, WI (US)

Correspondence Address: MACMILLAN SOBANSKI & TODD, LLC, ONE MARITIME PLAZA FIFTH FLOOR, 720 WATER STREET, TOLEDO, OH, 43604-1619, US

(21) Appl. No.: 11/436,963

(22) Filed: May 16, 2006

Related U.S. Application Data
(60) Provisional application No. 60/681,700, filed on May 17, 2005.

(51) Int. Cl. G01R 31/28

(52) U.S. Cl. 324/158.1

(57) ABSTRACT

A method of measuring the quality of a printed image, including the steps of: providing a substrate with a printed image thereon; obtaining a digital image of a part of the printed image using an image obtaining apparatus; and measuring one or more physical characteristics of the obtained digital image so as to provide an indication of the quality of the printed image.

### CROSS-REFERENCE TO RELATED APPLICATIONS

Applicants claim priority to U.S. Provisional Patent Application Ser. No. 60/681,700 filed May 17, 2005.

### STATEMENT REGARDING FEDERALLY SPONSORED RESEARCH OR DEVELOPMENT

Not Applicable.

### TECHNICAL FIELD

This invention relates to a method of, and apparatus for, measuring the quality of a printed image.

### BACKGROUND OF THE INVENTION

Printed images created using conventional presses, such as Rotogravure (Intaglio), Flexographic and Lithographic (Offset) presses, require the adjustment of many variables to create a suitable, high quality, e.g. up to 4500 dpi (dots per inch), reproduction of the original subject material. The adjustment of these variables, such as, pressure, ink viscosity and temperature, is commonly the responsibility of the press operator, who employs subjective evaluation of the quality of the printed image and adjusts these variables accordingly until the quality of the printed image is satisfactory.

Additional markings are commonly used to aid the press operator in optimizing the quality of the printed image. These markings are placed on an edge of a printing plate which is supported on a rotatable printing drum used to print the image, outside of the printed image area, and are printed coincidentally with the production image. These markings generally occupy a strip at each side of the printed image, which can be as wide as 2 cm. Since these markings do not form part of the production image they are always removed, by trimming, and are considered waste material. They are an added cost in producing the production image.

The substrate onto which the image is printed is often expensive and the removal of the print control markings would increase the available width of printing space for production, thus saving production costs. As a result it has become common practice for press operators to remove the print control markings from the surface of the printing plate prior to printing. However, this common practice removes the means of controlling the quality of the printed image, which is unsatisfactory and can often lead to the production image being of poor, and unacceptable, quality.

### BRIEF SUMMARY OF THE INVENTION

Therefore according to an aspect of the present invention there is provided a method of measuring the quality of a printed image, including the steps of: providing a substrate with a printed image thereon, the printed image including a pattern of a plurality of test elements; obtaining a digital image of the test elements from the printed image using an image obtaining apparatus; and measuring one or more physical characteristics of the test elements using the obtained digital image so as to provide an indication of the quality of the printed image.

The pattern is included in the image and by this we mean that the pattern forms part of the image, i.e. is provided within a periphery of the image. Furthermore, the pattern is of such a size as to be hidden from casual visual inspection of the printed image, thus ensuring it does not spoil the overall impression of the printed image. However, the plurality of test elements are of such detail that changes in their optical properties and dimensions indicate variances in print quality. Furthermore, when obtaining the digital image of the plurality of test elements, the image obtaining apparatus distinguishes between the plurality of test elements and the remainder of the printed image.

The one or more physical characteristics measured may include measuring an area occupied by each of the test elements, and the further step of comparing that measured area with an optimal area value, e.g. an area of the corresponding formation on the printing plate on the printing plate. The result from this measurement(s) can be used for comparison with an optimal area value, if the production printed image is printed to a satisfactory quality.

The test elements may be circular. In this case, a further physical characteristic measured may be a circularity function of each circular test element. The circularity function, C, of each circular test element is the square of the perimeter, P, of the circular test element divided by the area, A, of the circular test element. The circularity function, C, can be shown in the form of an equation as C=P²/A. The result from this measurement(s) can be used for comparison with an optimal circularity value for each test element, e.g. that for a perfect circle, and thus indicate whether the production printed image is printed to a satisfactory quality.

A yet further physical characteristic measured may include measuring an area occupied by each of the test elements, and determining what percentage of that area is covered by ink, thus giving an indication as to whether the printing variables, such as, pressure, ink viscosity and temperature are satisfactory or whether they need adjusting.

A yet further physical characteristic measured may be an average luminance of each of the test elements. By “average luminance” we mean the arithmetic mean of all luminance values for all of the pixels making up each test element. Again, the result from this measurement(s) can be used for comparison with an optimal average luminance value for each test element to indicate whether the production printed image is printed to a satisfactory quality.

A yet further physical characteristic measured may be an average color of each of the test elements. By “average color” we mean the arithmetic mean of all color values for all of the pixels making up each test element. The result from this measurement(s) can be used for comparison with an optimal average color value for each test element to indicate whether the production printed image is printed to a satisfactory quality.

The plurality of test elements may be positioned on a part of the substrate which has no ink printed thereon, such that the test elements are distinguishable from a remainder of the printed image

Beneficially, there may be five or more test elements. This ensures that a reliable measurement of the quality of the printed image can be achieved.

The obtained digital image may include a plurality of pixels and the method may include measuring, for a test area of pixels within the obtained digital image, a physical characteristic of each pixel and comparing the measured physical characteristic of each pixel within the test area with the measured physical characteristic of an adjacent pixel.

The method may include comparing the measured physical characteristic of each pixel within the test area with the measured physical characteristic of two or more adjacent pixels.

The test area of pixels within the obtained digital image may include a plurality of pixels in rows and columns and the method may include comparing the measured physical characteristic of each pixel within the test area with the measured physical characteristic of a first adjacent pixel located in the same row and with the measured physical characteristic of a second adjacent pixel located in the same column.

The method may include comparing the measured physical characteristic of each pixel within the test area with the measured physical characteristic of an adjacent pixel located in an adjacent row or column.

The physical characteristic measured may be a luminance of each pixel.

Where the obtained digital image is a color image, the method may include the step of converting the color image to a gray-scale image before a physical characteristic of each pixel is measured. The method may include the subsequent step of enhancing the gray-scale image.

Enhancement of the gray-scale image may be effected using an interpolation technique. In one example, the interpolation technique may include adjusting a luminance value for each pixel within the test area of the gray-scale image if the luminance value of that pixel differs from an average luminance value for all of the pixels within the test area of the gray-scale image.

The method may include the step of providing a viewable output indicative of the quality of the printed image.

According to a second aspect of the present invention there is provided an image obtaining apparatus, the apparatus including a device to obtain a digital image of a pattern of a plurality of test elements of an image printed on a substrate, a storage device to store information relating to the obtained digital image, and a device to measure one or more physical characteristics of the test elements using the obtained digital image so as to provide information indicative of the quality of the printed image.

The image obtaining apparatus may be hand-held and may, for example, obtain a digital full-color high resolution image of the pattern. This has the advantage that a user can use the apparatus to assess the quality of a printed image at any time after the image has been printed, e.g. before or after the printed image has been transported from a location where it was printed.

Alternatively, the image obtaining apparatus may be an integral part of a printing apparatus which prints the image onto the substrate, in which case the image obtaining apparatus may be configured to acquire a digital image of the test elements synchronously at the same rate that the images are printed by the printing apparatus. This has the advantage that an operator of the printing apparatus can determine, whilst printing a plurality of prints of the image, whether the print quality is satisfactory, and, if required, alter variables such as pressure, ink viscosity and temperature until the print quality is satisfactory. The variables of the printing apparatus may be adjusted automatically in response to a signal(s) from the image obtaining apparatus, thus providing an iterative process to increase the quality of the image being printed.

The apparatus may include a device to provide a viewable output indicative of the quality of the printed image, e.g. a digital screen.

According to a third aspect of the invention there is provided a printing member, e.g. a printing plate, for printing an image onto a substrate, the printing member including a plurality of formations defining an image to be printed onto the substrate and a plurality of further formations, which are provided within a periphery of the plurality of formations defining the image to be printed, and which define a plurality of test elements.

The further formations defining the plurality of test elements may each be circular, thus, when the printing member is used, the further formations print onto the substrate a plurality of circular test elements within the periphery of the printed image.

The formations defining an image to be printed may be configured such that when the image is printed the printed test elements are positioned on a part of the substrate, e.g. a rectangle enclosing the plurality of test elements, which has no ink printed thereon, such that the printed test elements are distinguishable from a remainder of the printed image.

Beneficially, there may be five or more further formations defining the plurality of test elements.

According to a fourth aspect of the invention there is provided a printing member for printing an image onto a substrate, the printing member including a plurality of ink-receptive areas defining an image to be printed onto the substrate and a plurality of further ink-receptive areas, which are provided within a periphery of the plurality of ink-receptive areas defining the image to be printed, and which define a plurality of test elements.

The further ink-receptive areas defining the plurality of test elements may each be circular, thus, when the printing member is used, the further ink-receptive areas print onto the substrate a plurality of circular test elements within the periphery of the printed image.

The ink-receptive areas defining an image to be printed may be configured such that when the image is printed the printed test elements are positioned on a part of the substrate, e.g. a rectangle enclosing the plurality of test elements, which has no ink printed thereon, such that the printed test elements are distinguishable from a remainder of the printed image.

Beneficially, there may be five or more further ink-receptive areas defining the plurality of test elements.

Various objects and advantages of the invention will become apparent from the following detailed description of the invention and the accompanying drawings.

### BRIEF DESCRIPTION OF THE DRAWINGS

FIG. 1 is a magnified plan view of a pattern of a plurality of test elements in accordance with the present invention;

FIG. 2 is a magnified plan view of an alternative pattern of a plurality of test elements in accordance with the present invention;

FIG. 3 is a perspective view from one side an above of a hand-held image obtaining apparatus in accordance with the present invention;

FIG. 4 is a magnified plan view of a pattern of a plurality of test elements showing a print quality error highlighted by some of the test elements;

FIG. 5 is a magnified plan view of an alternative pattern of a plurality of test elements showing a print quality error highlighted by some of the test elements;

FIG. 6 is a flowchart of a first example of a method in accordance with the present invention;

FIG. 7 is a magnified plan view of one of the test elements of FIG. 1;

FIG. 8 is a flow chart of a second example of a method in accordance with the present invention; and

FIG. 9 is a view of a pixel target area used a second example of a method in accordance with the present invention.

### DETAILED DESCRIPTION OF THE INVENTION

Referring to FIG. 1, this shows a magnified plan view of a pattern 10 of a plurality of test elements in accordance with the present invention. The pattern 10 is produced by a plurality of formations provided on a printing member, e.g. a printing plate (not shown), which is supported on a rotatable drum (also not shown) of a printing apparatus within a periphery of a plurality of formations defining an image 12 to be printed onto a substrate 14. The size of the pattern 10 is such that when the image 12 is printed, the pattern 10 is hidden from casual visual inspection of the printed image 12, thus ensuring it does not spoil the overall impression of the printed image 12. The location of the pattern 10 is, however, known by an operator of the printing apparatus (or any other appropriate third party wishing to check the quality of the image), so that he/she can use the pattern 10 to measure the quality of the printed image 12.

Alternatively, the printing member may be in the form of a printing plate for use in offset, e.g. lithographic, printing. In this case the pattern 10 is produced by a plurality of ink-receptive areas provided on the printing plate within a periphery of a plurality of other ink-receptive areas defining the image 12 to be printed onto a substrate 14.

The pattern 10 has six test elements, numbered 21 to 26, each of which is circular, although they could be any other shape. The six test elements 21 to 26 is this example are aligned so that they form a single row extending in one direction and are each 25 μm in diameter with the centers of adjacent test elements 21 to 26 spaced at 50 μm. Preferably, the diameter of each test element 21 to 26 is at least twice the diameter of the dots making up a remainder of the printed image 12.

The six test elements 21 to 26 of the pattern 10 can be printed in any of the several colors conventionally used in printing images, such as, for example, cyan, magenta, yellow or black. This allows the pattern 10 to be further disguised from casual visual inspection of the printed image 12.

It is important that each of the formations on the printing plate corresponding to each of the six test elements 21 to 26 is as close to a perfect circle as possible so that an accurate measurement of the quality of the printed image 12 can be made (discussed later). Of course, whatever shape the test elements are, their shape and area of their corresponding formations on the printing plate must be accurately known prior to printing. The number and size of test elements 21 to 26 should, preferably, be determined by the image 12 to be printed and the type of printing apparatus and substrate to be used. For example, when printing an image onto a substrate of corrugated board, the number of test elements should, preferably, be increased so the pattern spans at least three flutes of the corrugated board. Alternatively, when printing on paper, film or thin card, a minimum of five test elements should, preferably, be used.

The test elements 21 to 26 in this example are each printed in a different color, which allows the operator of the printing apparatus to assess the quality of each stage of the printing process. The test element 21 is three-color black (i.e. cyan, magenta and yellow), the test element 22 is cyan, the test element 23 is magenta, the test element 24 is yellow, the test element 25 is black and the test element 26 is four-color black (i.e. cyan, magenta, yellow and black). The presence of the three- and four-color black test elements 25, 26 is so that the operator of the printing apparatus can assess the alignment of one color print to the next (see FIGS. 4 and 5, discussed later).

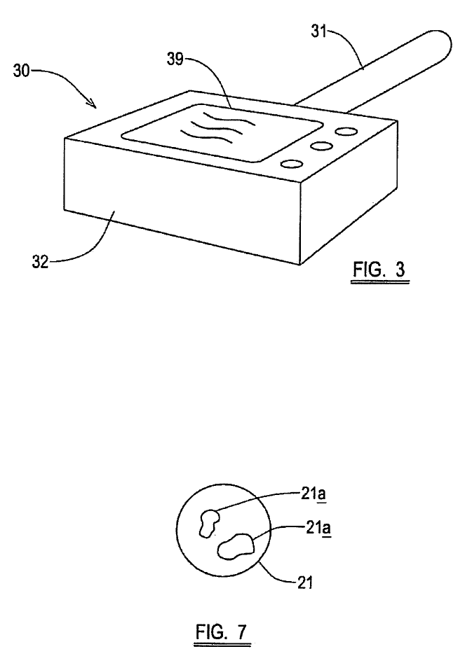

The six test elements 21 to 26 are positioned on a part 16 of the substrate 14 which has no ink printed thereon, such that the six test elements 21 to 26 are distinguishable from a remainder of the printed image 12 by an image obtaining apparatus 30 (see FIG. 3, discussed later). The part 16 in this example is a rectangle measuring 325 μm by 75 μm which encloses all six test elements 21 to 26. Preferably, the width of the part 16 is at least three times that of the diameter of each test element 21 to 26. This has the added advantage of avoiding problems during printing the image 12, such as ink splatter (known as ‘fogging’). It must, however, be appreciated that the part 16 could be any other appropriate shape, so long as it encloses all of test elements of the pattern and can be distinguished from the remainder of the printed image 12 by the image obtaining apparatus 30.

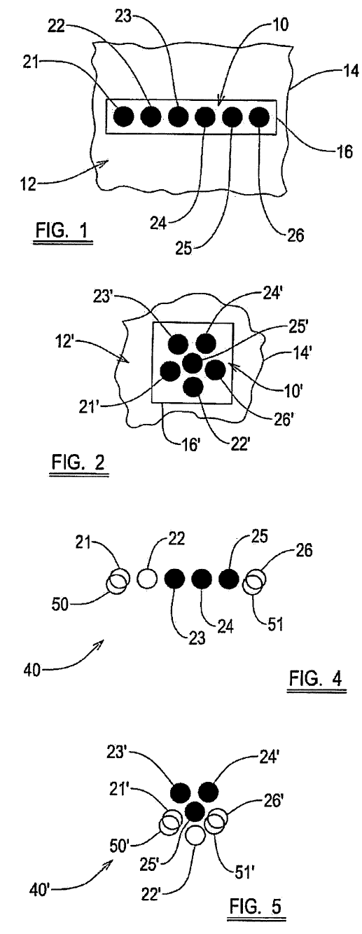

It must also be appreciated that the test elements 21 to 26 of the pattern 10 could be provided in any other appropriate array, such as the pattern 10′ shown in FIG. 2. Like components of the pattern 10′, as compared with the pattern 10, are indicated by the addition of a prime symbol to the reference numeral.

FIG. 3 shows a schematic perspective view of an image obtaining apparatus 30 in accordance with the second aspect of the present invention. In this example, the apparatus 30 is hand-held, thus allowing the operator of the printing apparatus or any other person to measure the quality of the image 12 printed by the printing apparatus. This ensures that the quality of the image 12 still can be measured even when the printed image 12 has been transported to a different location from that where the image 12 was printed.

The image obtaining apparatus 30 has a housing 32 with a handle 31. The housing 32 has an opening in its underside (not shown) which is covered by glass or a transparent plastic. The working components of the apparatus 30, which are supported in the housing 32, include a plurality of image sensors, such as CCD (Charge-Coupled) or CMOS (Complimentary Metal-Oxide Semiconductor) image sensors, a lamp to radiate light through the glass and onto the pattern 10 or 10′ and a battery as a power source. Each image sensor is a collection of tiny light-sensitive diodes or photosites, which convert light into an electrical charge. The photosites and are sensitive to light, e.g. the brighter the light, the greater the electrical charge produced, thus being able to distinguish between different colors of the pattern 10, 10′ and the part 16.

The image obtaining apparatus 30 in this example is capable of obtaining an image at a resolution of at least 7000 ppi (pixels per inch) in either full color or grey scale. It must, however, be appreciated that an image obtaining apparatus capable of obtaining a lower or higher resolution of image could also be used. Of course, the higher the resolution of the image obtained, the more accurate the measurement of the quality of the image 12.

The image obtaining apparatus 30 also includes a computer which is programmed to manipulate information received from the image sensors and to covert that information into a stored digital image of the pattern 10, which can, if desired be shown on a digital screen 33 of the apparatus 30 so that an operator can view a magnified digital image of the pattern 10. FIGS. 4 and 5 show two such obtained digital images 40, 40′. FIG. 4 is an image 40 corresponding to the pattern 10 in FIG. 1 and FIG. 5 is an image 40′ corresponding to the pattern 10′ in FIG. 2.

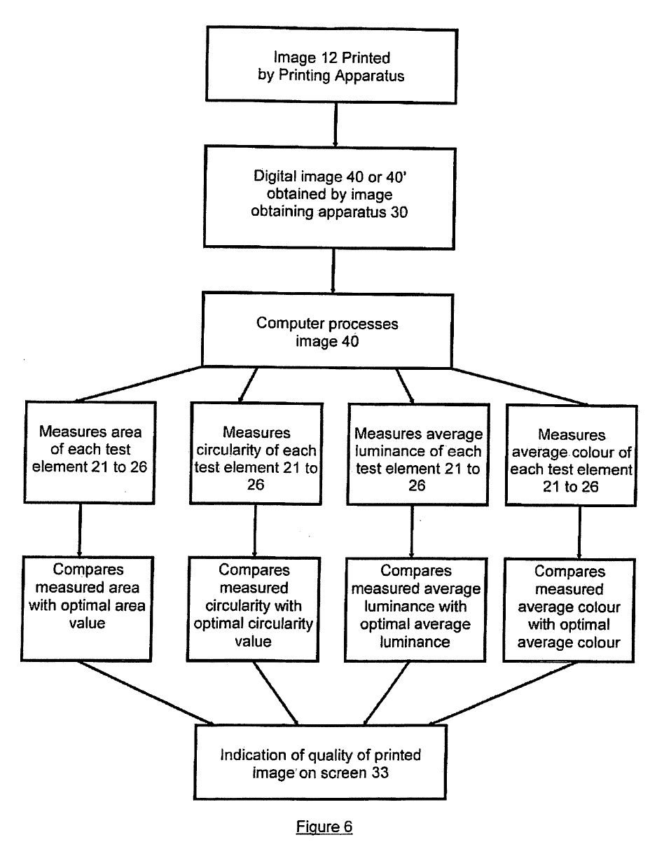

FIG. 6 shows a flowchart of a first example of a method in accordance with the present invention, which will be discussed below. Once the image 40 or 40′ has been obtained by the image obtaining apparatus 30, the computer then processes the image 40 or 40′ to measure the quality of the printed image 12. In this example, the computer first measures the area occupied by each test element 21 to 26 or 21′ to 26′ and compares this with the area each test element 21 to 26 or 21′ to 26′ should occupy (i.e. by comparison with the area of the corresponding formation on the printing plate used to print the image 12).

As, in this example, the patterns 10, 10′ includes circular test elements 21 to 26 or 21′ to 26′, the computer of the apparatus 30 also assesses the circularity of each of the test elements 21 to 26 or 21′ to 26′. This is achieved by the computer calculating the circularity function, C, of each circular test element 21 to 26, which is the square of the perimeter, P, of each circular test element 21 to 26 divided by its area, A (i.e. C=P²/A). The results from these measurements can be used for comparison with an optimal circularity value, i.e. the value of C for a perfect circle. For a perfect circle C=4π, and thus the closer the calculated C value for each test element 21 to 26 is to 4π, the better the alignment of the colors used during printing and thus better the print quality.

The computer also measures an area occupied by each of the test elements, and determines what percentage of that area is covered by ink, thus giving an indication as to whether the printing variables, such as, pressure, ink viscosity and temperature are satisfactory or whether they need adjusting. It may be the case that there are areas within the periphery of each test element 21 to 26 which are not covered by ink, which should be. This may be as a result of, for example, too much or too little printing pressure. The computer thus measures the total area of each test element 21 to 26 and then measures the total area of all of the non-inked areas within the periphery of each test element 21 to 26. Then, by dividing the latter by the former, the computer provides a percentage value for that test element 21 to 26. For example, the magnified view of the test element 21 shown in FIG. 7 has two sections 21 a, which are not covered by ink but should be. This test element 21 has a percentage coverage value of roughly 80%.

The computer also calculates the average luminance of each test element 21 to 26 or 21′ to 26′ by calculating the arithmetic mean of all luminance values for all of the pixels making up each test element 21 to 26 or 21′ to 26′. In addition, the computer also calculates the average color of each test element 21 to 26 or 21′ to 26′ by calculating the arithmetic mean of all color values for all of the pixels making up each test element 21 to 26 or 21′ to 26′.

When the computer has performed the above measurements and calculations, the computer then gives an indication as to the quality of the printed image 12, e.g. by providing a viewable output, such as a digital reading on the screen 33 of the apparatus 30. Such a viewable output may indicate to an operator of the printing apparatus which variables (e.g. ink pressure, ink viscosity and temperature) should be adjusted to improve the quality of the printed image. Alternatively, if the image obtaining apparatus 30 is provided as an integral part of a printing apparatus, the computer of the apparatus 30 may send a signal(s) to a computer operating the printing apparatus to adjust variables of the printing apparatus to improve the quality of the printed image 12 (i.e. an iterative process) until the quality of the printed image 12 is satisfactory.

The obtained images 40, 40′ shown in FIGS. 4 and 5 indicate that the cyan color ink in not aligned properly. This is shown in the test elements 21, 21′, 22, 22′ and 26, 26′ (which are shown in outline only to aid clarity). In the test elements 21, 21′ and 26, 26′ the cyan color component thereof, indicated by the peripheral outline at 50, 50′, is not aligned with the other color components of the test elements 21, 21′ and 26, 26′. Furthermore, the test element 22 is not aligned in a straight row with the other test elements 23, 24, 25 or the non-cyan components of the test elements 21, 26. This will be recognized by the computer of the apparatus 30, as the circularity of the test elements 21, 26 or 21′, 26′ will be poor. Furthermore, the computer will recognize that the test element 22 is not aligned with the other test elements 23, 24, 25, and that the test element 22′ is not properly aligned in the array of its pattern.

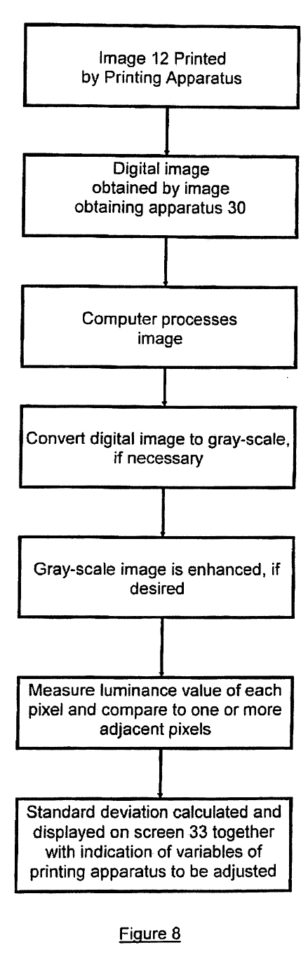

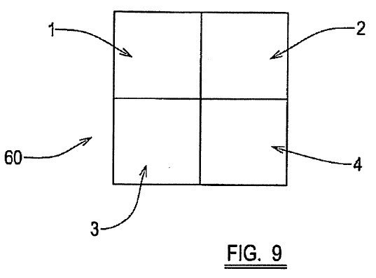

The method in accordance with the present invention can also be used to measure the quality of the printed image 12 even if no test elements as above described are present. Thus, the method in accordance with the present invention can be used to measure the quality of a printed image by examining a solid area of print, i.e. an area of the printed image which is 100% covered with the same color ink. A second example of a method in accordance with the present invention will be described hereinafter with reference to FIGS. 8 and 9.

It has been found that where the image obtaining apparatus 30 is able to obtain a high resolution digital image of a solid printed area of the printed image 12, for example a resolution greater than 7000 ppi (pixels per inch), it is possible to measure the quality of the printed image 12 from that obtained digital image. A flow chart of the second example of a method in accordance with the present invention for measuring the quality of a solid area of printed image is shown in FIG. 8.

In order to determine the quality of the printed image by looking at a solid printed area only of the printed image, it is beneficial, although not essential, if having obtained a color digital image using the image obtaining apparatus 30, to convert that obtained color digital image to a gray-scale digital image. A gray-scale digital image is one in which the absolute light reflectance (luminance) value of each pixel, regardless of its originating color before conversion, ranges from 0 to 255.

For example, after conversion to a gray-scale digital image, a dark red may have the same luminance value as a dark blue, and thus a original color will have no effect on any subsequent analysis in relation to the luminance of each pixel.

In order to assist in measuring the quality of the solid printed area of the printed image, it is beneficial, although not essential, to enhance the gray-scale digital image using an interpolation technique to make more visible areas of the printed image which are not of even quality, e.g. which show areas where ink has not adhered evenly to the substrate.

One such technique includes the step of adjusting the luminance value of each pixel in the gray-scale digital image by a factor determined by the difference of the luminance value of that pixel from the mean average pixel luminance value for all of the pixels of the gray-scale digital image.

This a performed by the computer of the image obtaining apparatus 30 which creates from the new luminance values for all the pixels an enhanced gray-scale digital image. The enhanced gray-scale digital image reveals inconsistencies in the quality of the printed image which would not otherwise be visible. In addition, as will become apparent from the description below, enhancing the gray-scale digital image accentuates, i.e. amplifies, differences in the luminance values of the pixels of the image, thus permitting improved accuracy in the calculations made (e.g. standard deviation, discussed below) as to the quality of the printed image.

For example, if an non-enhanced gray-scale digital image is used, it is often the case, although not always, that the calculated results are numerically too small such that any meaningful indication can be gained as to the quality of the printed image. Enhancing the gray-scale digital image prior to its assessment by the computer is therefore beneficial.

It must be appreciated, of course, that other techniques could be used to enhance the quality of the gray-scale digital image and/or that the above described technique could be repeated further to enhance the gray-scale digital image.

Once the gray-scale image has been enhanced, the computer of the image obtaining apparatus 30 then assesses the enhanced gray-scale digital image to measure the quality of the printed image 12. The computer measures, for a test area of pixels within the enhanced gray-scale digital image, a luminance value of each pixel and compares the measured luminance value of each pixel with the measured luminance value of an adjacent pixel.

Advantageously, in this example the luminance value of each pixel is compared with a luminance value of three adjacent pixels, as will be readily apparent from the description below.

In order to compare the luminance value of each pixel with the luminance value of adjacent pixels, the computer of the image obtaining apparatus 30 uses a target 60 measuring two by two pixels (see FIG. 9) and moves this target 60 through a test area of the enhanced gray-scale digital image.

The target 60 thus includes four pixel locating areas which are labeled as 1 (positioned top left), 2 (top right), 3 (bottom left) and 4 (bottom right) in FIG. 9. Alternatively, the target 60 could include only two pixel locating areas, e.g. pixel locating areas 1 and 2. Alternatively still, the target 60 could include three pixel locating areas, e.g. being L-shaped and including pixel locating areas 1, 2 and 3.

In this example, the computer of the image obtaining apparatus 30 places the pixel locating area 1 on each pixel of a test area of the enhanced gray-scale digital image and measures the luminance value of that pixel, and the luminance value of each of the pixels falling in the pixel locating areas 2, 3 and 4. Preferably, the computer moves the target 60 rectilinearly along each pixel row of the test area, or alternatively each pixel column of the test area, of the enhanced gray-scale digital image until the target reaches the end of that row or column. The computer then moves the target 60 back to the start of an adjacent row or column and moves the target 60 along that row or column.

The test area in this example is a rectangle having x number of pixel columns and y number of pixel rows, the computer places the pixel locating area 1 on all but one row of pixels and on all but one column of pixels of the enhanced gray-scale digital image. This is because for one pixel row and one pixel column at an edge of the enhanced gray-scale digital image, a pixel falling in the pixel locating area 1 could only be compared with one adjacent pixel. Although such a comparison could be made in accordance with the method of the present invention, e.g. by using a target having two pixel locating areas, it would not be consistent with the comparisons made throughout the remainder of the enhanced gray-scale digital image.

The computer of the image obtaining apparatus 30 then calculates the difference between the luminance value for the pixel falling in the pixel locating area 1 and the luminance values for the pixels falling in the pixel locating areas 2, 3 and 4. In this example, one of two calculations can be used by the computer, although it must be appreciated that any other appropriate calculation could be used. The first calculates the sum of the absolute differences between the luminance values of the pixels falling in pixel locating areas 1, 2, 3 and 4 using the following equation:
(abs(1−2)+abs(2−4)+abs(4−3)+abs(3−1)+abs(1−4)+abs(3−2)).

The second calculates the sum of the absolute cross differences between the luminance values of the pixels diagonally adjacent each other (i.e. the difference between the luminance values for the pixels falling within the pixel locating areas 1 and 4, and the difference between the luminance values for the pixels falling within the pixel locating areas 2 and 3) using the following equation:
=(abs(1−4)+abs(2−3)).

The term “abs” used in the above equations has its usually mathematical meaning, i.e., abs(x−y)=√((x−y)²).

Results obtained by the computer using either of the above equations do not differ greatly and thus either could be used without affect the overall assessment of the quality of the solid printed area of the printed image 12.

The computer then stores in its memory facility the results of the difference calculation for that target location and then moves the target 60 onto the next adjacent pixel in that row or column as the case may be, where the computer makes the difference calculation, records the result in its memory facility and moves on, etc.. The results are, for example, saved in the computer's memory facility in tabular form with each entry from a pixel location in the enhanced image gray-scale digital image.

Once the target has been moved over the test area of the enhanced gray-scale digital image, the computer uses the tabulated results to calculate the standard deviation of the obtained absolute difference (or absolute cross difference) luminance values for the pixels within the test area of the gray-scale digital image and provide a viewable output, such as a digital reading on the screen 33. As the gray-scale digital image is enhanced before assessment by the computer, the calculated standard deviation will be larger (when compared to the assessment of an identical image which has not been enhanced), thus permitting improved accuracy as to the quality of the printed image. Such an output may indicate to the operator of the printing apparatus which variables of the printing apparatus should be adjusted to improve the quality of the printed image.

If an operator uses the image obtaining apparatus 30 to obtain a digital image of a part of the printed image where the plurality of test elements should be, and no test elements 21 to 26 can be found by the image obtaining apparatus 30, the computer will measure the quality of the printed image 12 by assessing a solid printed area of the obtained digital image using the second example of the method in accordance with the present invention as above described. Even if the computer locates the test elements 21 to 26, the computer may also measure the quality of the printed image 12 by assessing also a solid printed area of the obtained digital image.

The features disclosed in the foregoing description, or the following claims, or the accompanying drawings, expressed in their specific forms or in terms of a means for performing the disclosed function, or a method or process for attaining the disclosed result, as appropriate, may, separately, or in any combination of such features, be utilized for realizing the invention in diverse forms thereof.

It will be appreciated that various modifications and changes may be made to the above described preferred embodiment of without departing from the scope of the following claims.

1. A method of measuring the quality of a printed image, including the steps of:
providing a substrate with a printed image thereon;
obtaining a digital image of a part of the printed image using an image obtaining apparatus; and
measuring one or more physical characteristics of the obtained digital image so as to provide an indication of the quality of the printed image.

2. A method according to claim 1 wherein the printed image includes a pattern of a plurality of test elements and the method includes obtaining a digital image of the plurality of test elements.

3. A method according to claim 2 wherein the one or more physical characteristics measured includes measuring an area of occupied by each of the test elements, and the method includes the further step of comparing that measured area to an optimal area value.

4. A method according to claim 2 wherein the test elements are circular.

5. A method according to claim 4 wherein a further physical characteristic measured is a circularity function of each test element, and the method includes the further step of comparing the measured circularity value of each test element with an optimal circularity value.

6. A method according to claim 2 wherein a further physical characteristic measured is an average luminance of each of the test elements.

7. A method according to claim 2 wherein a further physical characteristic measured is an average color of each test element.

8. A method according to claim 2 wherein the plurality of test elements are positioned on a part of the substrate which has no ink printed thereon, such that the test elements are distinguishable from a remainder of the printed image.

9. A method according to claim 2 wherein five or more test elements are provided.

10. A method according to claim 1 wherein the obtained digital image includes a plurality of pixels and the method includes measuring, for a test area of pixels within the obtained digital image, a physical characteristic of each pixel and comparing the measured physical characteristic of each pixel within the test area with the measured physical characteristic of an adjacent pixel.

11. A method according to claim 10 wherein the method includes comparing the measured physical characteristic of each pixel within the test area with the measured physical characteristic of two or more adjacent pixels.

12. A method according to claim 1 1 wherein the test area of pixels within the obtained digital image includes a plurality of pixels in rows and columns and the method includes comparing the measured physical characteristic of each pixel within the test area with the measured physical characteristic of a first adjacent pixel located in the same row and with the measured physical characteristic of a second adjacent pixel located in the same column.

13. A method according to claim 2 wherein the method includes comparing the measured physical characteristic of each pixel within the test area with the measured physical characteristic of an adjacent pixel located in an adjacent row or column.

14. A method according to claim 10 wherein the physical characteristic measured is a luminance of each pixel.

15. A method according to claim 10 wherein the obtained digital image is a color image and the method includes the step of converting the color image to a gray-scale image before a physical characteristic of each pixel is measured.

16. A method according to claim 15 wherein the method includes the subsequent step of enhancing the gray-scale image.

17. A method according to claim 16 wherein the enhancement of the gray-scale image is performed using an interpolation technique.

18. A method according to claim 17 wherein the interpolation technique includes adjusting a luminance value for each pixel within the test area of the gray-scale image if a luminance value of that pixel differs from an average luminance of all of the pixels within the test area of the gray-scale image.

19. A method according to claim 1 including the step of providing a viewable output indicative of the quality of the printed image.

20. An image obtaining apparatus, the apparatus including a device to obtain a digital image of a pattern of a plurality of test elements of an image printed on a substrate, a storage device to store information relating to the obtained digital image, and a device to measure one or more physical characteristics of the test elements using the obtained digital image so as to provide information indicative of the quality of the printed image.

21. An image obtaining apparatus according to claim 20 which is hand-held.

22. An image obtaining apparatus according to claim 20 which is an integral part of a printing apparatus which prints the image onto the substrate.

23. An image obtaining apparatus according to claim 20 including a device to provide a viewable output indicative of the quality of the printed image.

24. An image obtaining apparatus according to claim 23 wherein the device to provide the viewable output is a digital screen.

25. A printing member for printing an image onto a substrate, the printing member including a plurality of formations defining an image to be printed onto the substrate and a plurality of further formations, which are provided within a periphery of the plurality of formations defining the image to be printed, and which define a plurality of test elements.

26. A printing member according to claim 25 wherein the further formations defining the plurality of test elements are each circular.

27. A printing member according to claim 25 wherein the formations defining an image to be printed are configured such that when the image is printed the printed test elements are positioned on a part of the substrate which has no ink printed thereon, such that the printed test elements are distinguishable from a remainder of the printed image.

28. A printing member according to claim 25 wherein five or more further formations defining the plurality of test elements are provided.

29. A printing member for printing an image onto a substrate, the printing member including a plurality of ink-receptive areas defining an image to be printed onto the substrate and a plurality of further ink-receptive areas, which are provided within a periphery of the plurality of ink-receptive areas defining the image to be printed, and which define a plurality of test elements.

30. A printing member according to claim 29 wherein the further ink-receptive areas defining the plurality of test elements are each circular.

31. A printing member according to claim 29 wherein the ink-receptive areas defining an image to be printed are configured such that when the image is printed the printed test elements are positioned on a part of the substrate which has no ink printed thereon, such that the printed test elements are distinguishable from a remainder of the printed image.

32. A printing member according to claim 29 wherein five or more further ink-receptive areas defining the plurality of test elements are provided.
